(19) United States
(12) Patent Application Publication
(10) Pub. No.: US 2025/0210313 A1
(43) Pub. Date: Jun. 26, 2025

(54) APPARATUS FOR PROCESSING A SUBSTRATE

(71) Applicant: Samsung Electronics Co., Ltd., Suwon-si (KR)

(72) Inventors: Sunwoo BANG, Suwon-si (KR); Minsu LEE, Suwon-si (KR); Yeontae KIM, Suwon-si (KR); Hyeonjin JEON, Suwon-si (KR); Hyeongun JEON, Suwon-si (KR)

(73) Assignee: Samsung Electronics Co., Ltd., Suwon-si (KR)

(21) Appl. No.: 18/671,496

(22) Filed: May 22, 2024

(30) Foreign Application Priority Data
Dec. 20, 2023 (KR) 10-2023-0186518

(51) Int. Cl. H01J 37/32; C23C 16/455; C23C 16/458; H01L 21/67

(52) U.S. Cl. CPC H01J 37/3244; C23C 16/45565; C23C 16/45574; C23C 16/4583; H01J 2237/334; H01L 21/67069

(57) ABSTRACT

An apparatus for processing a substrate, the apparatus comprising a reaction chamber configured to receive the substrate, a support arranged in the reaction chamber configured to support the substrate, and a showerhead arranged between the reaction chamber and the support configured to inject a reaction gas to the substrate on the support. A diameter of the showerhead is longer than a diameter of the support. A radial difference between the diameter of the showerhead and the diameter of the support is no less than half of a gap between the showerhead and the support.

### CROSS-RELATED APPLICATION

This application claims priority under 35 USC § 119 to Korean Patent Application No. 10-2023-0186518, filed on Dec. 20, 2023 in the Korean Intellectual Property Office (KIPO), the contents of which are herein incorporated by reference in their entirety.

### BACKGROUND

Various example embodiments relate to an apparatus for processing a substrate. More particularly, various example embodiments relate to an apparatus for processing a semiconductor substrate using plasma.

Generally, an apparatus for processing a substrate using plasma may form a layer on the substrate, or etch a layer on the substrate. The apparatus may include a reaction chamber, a support, a showerhead, etc. The reaction chamber may be configured to receive the substrate. The support may be configured to support the substrate. The showerhead may be configured to inject a reaction gas to the substrate.

According to related arts, a distribution of the plasma may be controlled by changing a structure of the showerhead. However, it may be difficult to accurately control the distribution of the plasma only using the structure change of the showerhead.

### SUMMARY

Various example embodiments provide an apparatus for processing a substrate that may be capable of improving a distribution of plasma.

According to various example embodiments, there may be provided an apparatus for processing a substrate, the apparatus comprising a reaction chamber configured to receive the substrate, a support arranged in the reaction chamber configured to support the substrate, and a showerhead arranged between the reaction chamber and the support configured to inject a reaction gas to the substrate on the support. A diameter of the showerhead is longer than a diameter of the support. A radial difference between the diameter of the showerhead and the diameter of the support is no less than half of a gap between the showerhead and the support.

According to various example embodiments, there may be provided an apparatus for processing a substrate, the apparatus comprising a reaction chamber configured to receive the substrate, a support in the reaction chamber to support the substrate, and a showerhead between the reaction chamber and the support configured to inject a reaction gas to the substrate on the support. A diameter of the showerhead is longer than a diameter of the support. A gap between an outer circumferential surface of the showerhead and an inner wall of the reaction chamber is greater than a thickness of the showerhead.

According to various example embodiments, there may be provided an apparatus for processing a substrate, the apparatus comprising a reaction chamber configured to receive the substrate, a support in the reaction chamber configured to support the substrate; and a showerhead between the reaction chamber and the support configured to inject a reaction gas to the substrate on the support. The showerhead comprises a plurality of injection holes configured to inject the reaction gas, a plurality of plasma holes configured to allow a plasma to pass from a first plasma region into a second plasma region, and a plurality of connections connected between the showerhead and an inner wall of the reaction chamber. A diameter of the showerhead is longer than a diameter of the support. A radial difference between the diameter of the showerhead and the diameter of the support is no less than half of a gap between the showerhead and the support. A gap between an outer circumferential surface of the showerhead and an inner wall of the reaction chamber is greater than a thickness of the showerhead.

According to various example embodiments, the diameter of the showerhead may be longer than the diameter of the support. In this condition, a ratio of the difference between the diameter of the showerhead and the diameter of the support with respect to the gap between the showerhead and the support may be optimally set. Further, a ratio of the gap between the outer circumferential surface of the showerhead and the inner wall of the reaction chamber with respect to the thickness of the showerhead may also be optimally set. Thus, the plasma may have an improved distribution between the showerhead and the support by setting the ratios.

### BRIEF DESCRIPTION OF THE DRAWINGS

Various example embodiments will be more clearly understood from the following detailed description taken in conjunction with the accompanying drawings. FIGS. 1 to 6 represent non-limiting, various example embodiments as described herein.

FIG. 1 is a cross-sectional view illustrating an apparatus for processing a substrate in accordance with various example embodiments;

FIG. 2 is a plan view illustrating a showerhead of the apparatus in FIG. 1;

FIG. 3 is an image showing a distribution of plasma generated using a conventional apparatus;

FIG. 4 is an image showing a distribution of plasma generated using the apparatus in FIG. 1;

FIG. 5 is a cross-sectional view illustrating an apparatus for processing a substrate in accordance with various example embodiments; and

FIG. 6 is a plan view illustrating a showerhead of the apparatus in FIG. 5.

### DETAILED DESCRIPTION

Hereinafter, various example embodiments will be explained in detail with reference to the accompanying drawings.

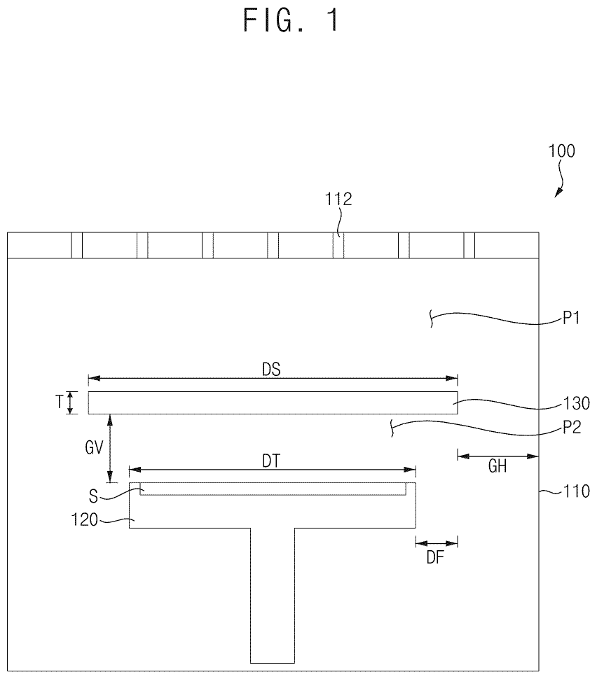

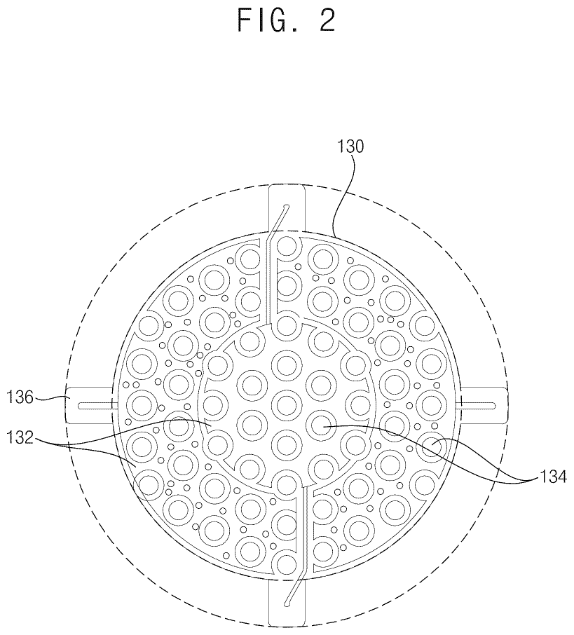

FIG. 1 is a cross-sectional view illustrating an apparatus for processing a substrate in accordance with various example embodiments, and FIG. 2 is a plan view illustrating a showerhead of the apparatus in FIG. 1.

Referring to FIGS. 1 and 2, an apparatus 100 for processing a substrate in accordance with various example embodiments may correspond to a capacitively coupled plasma (CCP) type apparatus. The CCP type apparatus may apply a radio frequency (RF) power to opposite electrodes to generate plasma from a reaction gas using an RF electric field between the electrodes. The CCP type apparatus may include a deposition apparatus configured to form a layer on a substrate, particularly, a semiconductor substrate, an etching apparatus configured to etch a layer on a substrate using the plasma, etc., but not limited thereto.

The apparatus 100 may include a reaction chamber 110, a support 120, a showerhead 130, etc. That is, the apparatus 100 may include the showerhead 130 as a plasma generator.

The reaction chamber 110 may have an inner space configured to receive a semiconductor substrate S. The reaction chamber 110 may have a plasma space where plasma may be formed from a reaction gas. A plurality of holes 112 through which the reaction gas may be introduced may be formed through an upper surface of the reaction chamber 110. A shutter configured to open/close a passage through which the semiconductor substrate S may enter may be arranged at a sidewall of the reaction chamber 110.

The support 120 may be arranged in a lower space of the reaction chamber 110. The semiconductor substrate S may be placed on an upper surface of the support 120. The support 120 may include an electrostatic chuck (ESC) or a heated pedestal. An RF power source may be connected to the support 120 so that the support 120 may function as a lower electrode. A matcher may be arranged between the RF power source and the support 120.

The showerhead 130 may be arranged in an upper space of the reaction chamber 110. An RF power source may be connected to the showerhead 130 so that the showerhead 130 may function as an upper electrode. The showerhead 130 may include an insulation material.

In various example embodiments, the showerhead 130 may be horizontally arranged in the plasma space to divide the plasma space into a first plasma region P1 and a second plasma region P2. The first plasma region P1 may be positioned over the showerhead 130. The second plasma region P2 may be positioned under the showerhead 130.

In various example embodiments, the showerhead 130 may include a plurality of injection holes 132, a plurality of plasma holes 134 and a plurality of connections 136.

The injection holes 132 may be extended from the upper surface to a lower surface in the showerhead 130. That is, an upper end of each of the injection holes 132 may be exposed through the upper surface of the showerhead 130, and a lower end of each of the injection holes 132 may be exposed through the lower surface of the showerhead 130. The reaction gas may be introduced into the showerhead 130 through the upper ends of the injection holes 132. The reaction gas may then be injected to the semiconductor substrate S on the support 120 through the lower ends of the injection holes 132.

The plasma holes 134 may be extended from the upper surface to the lower surface in the showerhead 130. That is, an upper end of each of the plasma holes 134 may be exposed through the upper surface of the showerhead 130. A lower end of each of the plasma holes may be exposed through the lower surface of the showerhead 130. The plasma may be introduced into the showerhead 130 through the upper ends of the plasma holes 134. The plasma may then be applied to the semiconductor substrate S on the support 120 through the lower ends of the plasma holes 134.

In various example embodiments, a ratio of a total area of the plasma holes 134 with respect to an area of the showerhead 130 may be no more than about 70%, but example embodiments are not limited thereto. When the ratio of the total area of the plasma holes 134 with respect to the area of the showerhead 130 may be about 70% or more, a great amount of the plasma may pass through from the first plasma region P1 to the second plasma region P2 through the plasma holes 134, and the distribution of the plasma may be degraded. Thus, the distribution of the plasma in the second plasma region P2 may be improved by providing the ratio of the total area of the plasma holes 134 with respect to the area of the showerhead 130 to be no more than about 70%.

The connections 136 may be extended from an outer circumferential surface of the showerhead 130 to an inner wall of the reaction chamber 110. Particularly, the connections 136 may be extended from the outer circumferential surface of the showerhead 130 along a radial direction of the showerhead 130, but example embodiments are not limited thereto. In various example embodiments, the connections 136 may include four connections arranged spaced apart from each other by a uniform angle of about 90°, but example embodiments are not limited thereto. For example, the connections 136 may include two, three or five connections or more spaced apart from each other by a uniform gap.

In various example embodiments, a ratio of an area of spaces between the connections 136 with respect to an area of a space between the outer circumferential surface of the showerhead 130 and the inner wall of the reaction chamber 110 may be no less than about 80%, but example embodiments are not limited thereto. When the area of the spaces between the connections 136 may be about 80% or less of the area of the space between the outer circumferential surface of the showerhead 130 and the inner wall of the showerhead 130, the plasma may be restricted from passing through the spaces between the connections 136. Thus, the distribution of the plasma in the second plasma region P2 may also be improved by providing the ratio of the area of spaces between the connections 136 with respect to the area of the space between the outer circumferential surface of the showerhead 130 and the inner wall of the reaction chamber 110 to be no less than about 80%.

In various example embodiments, the showerhead 130 may have a diameter DS longer than a diameter DT of the support 120. Thus, the outer circumferential surface of the showerhead 130 may protrude horizontally from the outer circumferential surface of the support 120.

Particularly, in order to more uniformly distribute the plasma in the second plasma region P2, a radial difference DF between the diameter DS of the showerhead 130 and the diameter DT of the support 120 may be no less than half of a gap GV between the showerhead 130 and the support 120. That is, the gap GV between the showerhead 130 and the support 120 may be below two times the radial difference DF between the diameter DS of the showerhead 130 and the diameter DT of the support 120.

The radial difference DF between the diameter DS of the showerhead 130 and the diameter DT of the support 120 may be less than about half of the gap GV between the showerhead 130 and the support 120. In other words, the gap GV between the showerhead 130 and the support 120 may be greater than radial difference DF between the diameter DS of the showerhead 130 and the diameter DT of the support 120. Restated, the radial difference DF is equal to half of the difference in the diameter DS of the showerhead 130 and the diameter DT of the support 120. As an example, if a relatively large amount of plasma is applied to an edge portion of the semiconductor substrate S on the support 120, then a thickness of a deposited layer on the edge portion of the semiconductor substrate S may be thicker than a thickness of the layer on a central portion of the semiconductor substrate S. That is, the layer on the semiconductor substrate S may have poor thickness uniformity. However, in various example embodiments the plasma may be more uniformly distributed in the second plasma region P2 by providing the radial difference DF between the diameter DS of the showerhead 130 and the diameter DT of the support 120 with about half of the gap GV between the showerhead 130 and the support 120. As a result, the layer on the semiconductor substrate S may have improved thickness uniformity.

For example, the showerhead 130 having a thickness T of about 15 mm may be arranged in the reaction chamber 110. A gap GH between the outer circumferential surface of the showerhead 130 and the inner wall of the reaction chamber 110 may be about 194 mm. When the diameter DT of the support 120 may be about 330 mm and the diameter DS of the showerhead 130 may be about 400 m, the radial difference DF between the diameter DS of the showerhead 130 and the diameter DT of the support 120 may be about 35 mm on all sides. In this condition, in order to improve the distribution of the plasma in the second plasma region P2, the gap GV between the showerhead 130 and the support 120 may be about 69 mm which is less than two times the radial difference DF between the diameter DS of the showerhead 130 and the diameter DT of the support 120.

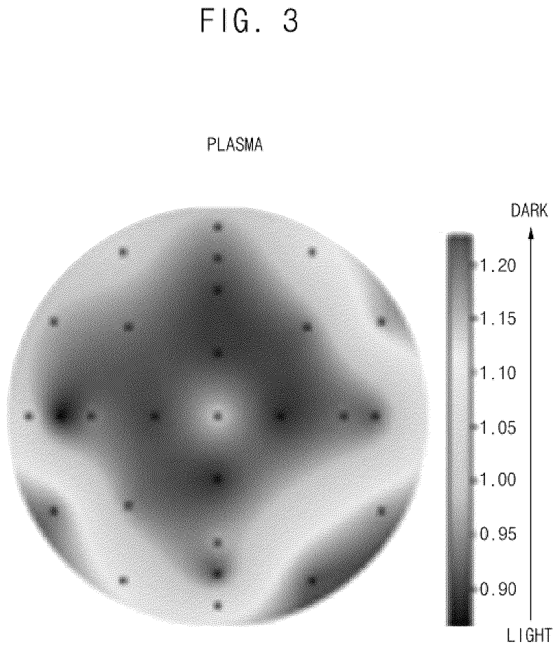

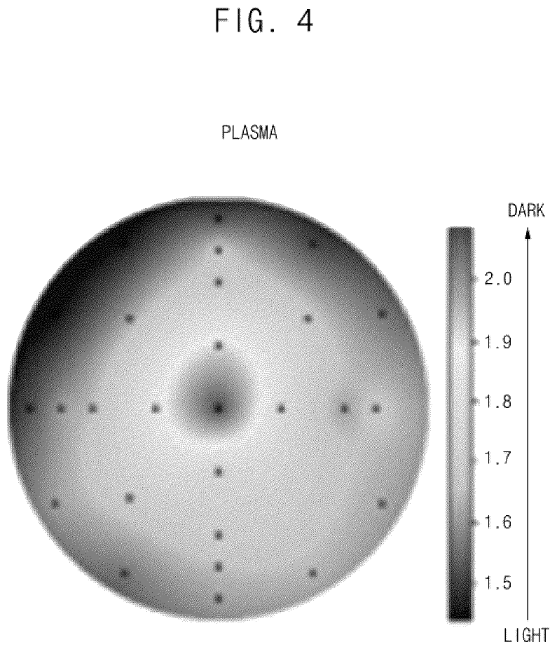

FIG. 3 is an image showing a distribution of plasma generated using a conventional apparatus and FIG. 4 is an image showing a distribution of plasma generated using the apparatus in FIG. 1.

As shown in FIG. 3, when a layer may be formed on a semiconductor substrate using a conventional apparatus, it can be noted that a thickness of the layer on an edge portion of the semiconductor substrate may be thicker than a thickness of the layer on a central portion of the semiconductor substrate. Thus, the layer may have poor thickness uniformity.

In contrast, as shown in FIG. 4, when a layer may be formed on a semiconductor substrate using the apparatus including the showerhead 130 of various example embodiments, it can be noted that a layer on the semiconductor substrate may have a more uniform thickness. Thus, the layer may have improved thickness uniformity.

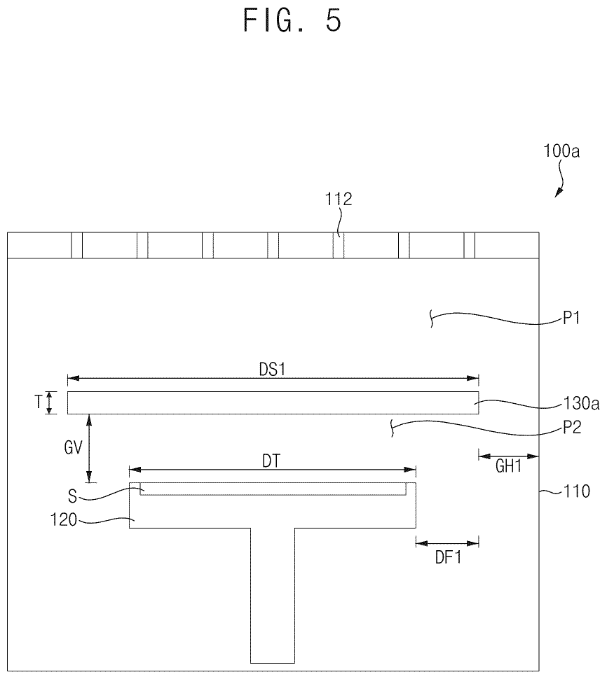

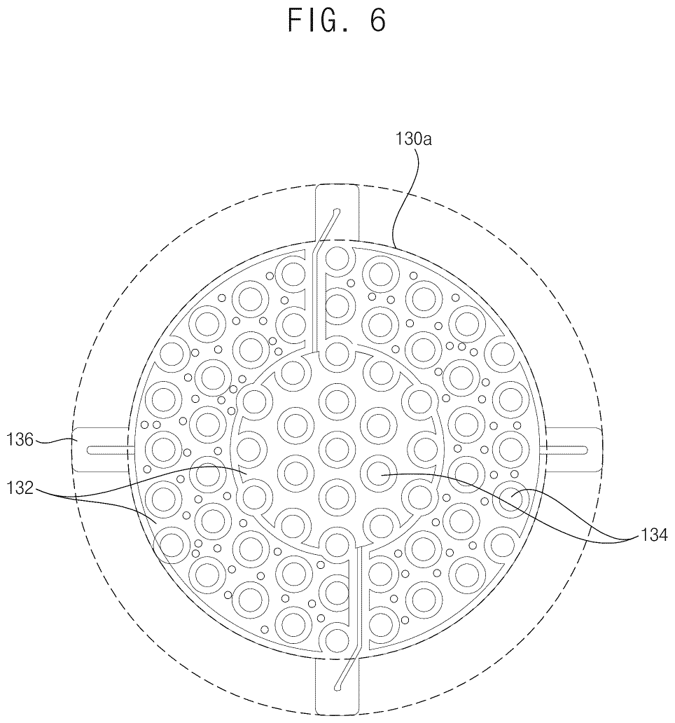

FIG. 5 is a cross-sectional view illustrating an apparatus for processing a substrate in accordance with various example embodiments and FIG. 6 is a plan view illustrating a showerhead of the apparatus in FIG. 5.

An apparatus 100a of various example embodiments may include elements substantially the same as those of the apparatus 100 in FIG. 1 except for a diameter of a showerhead. Thus, the same reference numerals may refer to the same elements and any further illustrations with respect to the same elements may be omitted herein for brevity.

Referring to FIGS. 5 and 6, a showerhead 130a of various example embodiments may have a diameter DS1 longer than the diameter DS of the showerhead 130 in FIG. 1. Thus, a length DF1 of the showerhead 130a horizontally protruded from the support 120 may also be longer than the length DF in FIG. 1. As a result, a gap GH1 between an outer circumferential surface of the showerhead 130a and the inner wall of the reaction chamber 110 may be narrower than the gap GH in FIG. 1.

In various example embodiments, the gap GH1 between the outer circumferential surface of the showerhead 130a and the inner wall of the reaction chamber 110 may be greater than a thickness T of the showerhead 130a. That is, the thickness T of the showerhead 130a may be no more than the gap GH1 between the outer circumferential surface of the showerhead 130a and the inner wall of the reaction chamber 110. When the gap GH1 between the outer circumferential surface of the showerhead 130a and the inner wall of the reaction chamber 110 may be less than the thickness T of the showerhead 130a, the showerhead 130a including an insulation material may be charged by dielectric charges to cause instability of the plasma. Thus, by setting the gap GH1 between the outer circumferential surface of the showerhead 130a and the inner wall of the reaction chamber 110 greater than the thickness T of the showerhead 130a, the charge of the showerhead 130a by the dielectric charges may be suppressed to reduce or prevent the instability of the plasma.

For example, when the showerhead 130a having a diameter of about 480 mm may be arranged in the reaction chamber 110, the gap GH1 between the outer circumferential surface of the showerhead 130a and the inner wall of the reaction chamber 110 may be about 194 mm. In this condition, the thickness T of the showerhead 130a may be about 15 mm corresponding to no more than the gap GH1 between the outer circumferential surface of the showerhead 130a and the inner wall of the reaction chamber 110.

According to various example embodiments, the diameter of the showerhead may be longer than the diameter of the support. In this condition, a ratio of the radial difference between the diameter of the showerhead and the diameter of the support with respect to the gap between the showerhead and the support may be optimally set. Further, a ratio of the gap between the outer circumferential surface of the showerhead and the inner wall of the reaction chamber with respect to the thickness of the showerhead may also be optimally set. Thus, the plasma may have an improved distribution between the showerhead and the support by setting the ratios.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

The foregoing is illustrative of various example embodiments and is not to be construed as limiting thereof. Although a few example embodiments have been described, those skilled in the art will readily appreciate that many modifications are possible in the various example embodiments without departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. An apparatus for processing a substrate, the apparatus comprising:
a reaction chamber configured to receive the substrate;
a support arranged in the reaction chamber configured to support the substrate; and
a showerhead arranged between the reaction chamber and the support configured to inject a reaction gas to the substrate on the support,
wherein a diameter of the showerhead is longer than a diameter of the support, and
wherein a radial difference between the diameter of the showerhead and the diameter of the support is no less than half of a gap between the showerhead and the support.

2. The apparatus of claim 1, wherein a gap between an outer circumferential surface of the showerhead and an inner wall of the reaction chamber is greater than a thickness of the showerhead.

3. The apparatus of claim 1, wherein the showerhead divides an inner space of the reaction chamber into a first plasma region and a second plasma region.

4. The apparatus of claim 3, wherein the first plasma region is over the showerhead and the second plasma region is under the showerhead.

5. The apparatus of claim 4, wherein the showerhead comprises:
a plurality of injection holes configured to inject the reaction gas; and
a plurality of plasma holes configured to allow a plasma to pass from the first plasma region into the second plasma region.

6. The apparatus of claim 5, wherein a ratio of a total area of the plasma holes with respect to an area of the showerhead is no more than about 70%.

7. The apparatus of claim 5, wherein the showerhead further comprises a plurality of connections connected between the showerhead and an inner wall of the reaction chamber.

8. The apparatus of claim 7, wherein a ratio of an area of spaces between the connections with respect to an area of a space between the showerhead and the inner wall of the reaction chamber is no less than 80%.

9. An apparatus for processing a substrate, the apparatus comprising:
a reaction chamber configured to receive the substrate;
a support in the reaction chamber to support the substrate; and
a showerhead between the reaction chamber and the support configured to inject a reaction gas to the substrate on the support,
wherein a diameter of the showerhead is longer than a diameter of the support, and
wherein a gap between an outer circumferential surface of the showerhead and an inner wall of the reaction chamber is greater than a thickness of the showerhead.

10. The apparatus of claim 9, wherein the showerhead divides an inner space of the reaction chamber into a first plasma region and a second plasma region.

11. The apparatus of claim 10, wherein the first plasma region is over the showerhead and the second plasma region is under the showerhead.

12. The apparatus of claim 11, wherein the showerhead comprises:
a plurality of injection holes configured to inject the reaction gas; and
a plurality of plasma holes configured to allow a plasma to pass from the first plasma region into the second plasma region.

13. The apparatus of claim 12, wherein a ratio of a total area of the plasma holes with respect to an area of the showerhead is no more than about 70%.

14. The apparatus of claim 12, wherein the showerhead further comprises a plurality of connections connected between the showerhead and an inner wall of the reaction chamber.

15. The apparatus of claim 14, wherein a ratio of an area of spaces between the connections with respect to an area of a space between the showerhead and the inner wall of the reaction chamber is no less than 80%.

16. An apparatus for processing a substrate, the apparatus comprising:
a reaction chamber configured to receive the substrate;
a support in the reaction chamber configured to support the substrate; and
a showerhead between the reaction chamber and the support configured to inject a reaction gas to the substrate on the support,
wherein the showerhead comprises
a plurality of injection holes configured to inject the reaction gas,
a plurality of plasma holes configured to allow a plasma to pass from a first plasma region into a second plasma region, and
a plurality of connections connected between the showerhead and an inner wall of the reaction chamber,
wherein a diameter of the showerhead is longer than a diameter of the support,
wherein a radial difference between the diameter of the showerhead and the diameter of the support is no less than half of a gap between the showerhead and the support, and
wherein a gap between an outer circumferential surface of the showerhead and an inner wall of the reaction chamber is greater than a thickness of the showerhead.

17. The apparatus of claim 16, wherein the showerhead divides an inner space of the reaction chamber into a first plasma region and a second plasma region.

18. The apparatus of claim 17, wherein the first plasma region is over the showerhead and the second plasma region is under the showerhead.

19. The apparatus of claim 16, wherein a ratio of a total area of the plasma holes with respect to an area of the showerhead is no more than about 70%.

20. The apparatus of claim 16, wherein a ratio of an area of spaces between the connections with respect to an area of a space between the showerhead and the inner wall of the reaction chamber is no less than 80%.
